(19) United States
(12) Patent Application Publication
(10) Pub. No.: US 2008/0196759 A1
(43) Pub. Date: Aug. 21, 2008

(54) Photovoltaic assembly with elongated photovoltaic devices and integrated involute-based reflectors

(76) Inventors: Thomas Brezoczky, Los Gatos, CA (US); Chris M. Gronet, Portola Valley, CA (US); Benyamin Buller, Cupertino, CA (US)

Correspondence Address: SOLYNDRA , INC, 47700 KATO ROAD, FREMONT, CA, 94538, US

(21) Appl. No.: 11/810,028

(22) Filed: Jun. 4, 2007

Related U.S. Application Data
(60) Provisional application No. 60/901,946, filed on Feb. 16, 2007.

(51) Int. Cl. H01L 31/052

(52) U.S. Cl. 136/246

(57) ABSTRACT

A photovoltaic assembly has elongated photovoltaic modules. The photovoltaic modules each have a substrate with a photovoltaic material disposed on the substrate. Each respective photovoltaic module lies in the concave structure of a corresponding concentrator assembly. The concentrator assemblies have surfaces made with reflective material that form such concave structures. The concentrator assemblies each transmit light to their corresponding photovoltaic module. The surfaces of each concentrator assembly are shaped at least in part as an involute of the surface of their corresponding photovoltaic modules, and do not exceed the height of the their corresponding module. A frame is provided having a first support and a second support, where the modules extend between the supports. The concentrator is mechanically attached to the frame. A substantial portion of light striking the concentrator is ultimately redirected to the modules without associated tracking and/or control devices.

### CROSS-REFERENCE TO RELATED APPLICATION

This application claims benefit under 35 U.S.C. § 119(e), of U.S. Provisional Patent Application No. 60/901,946, filed on Feb. 16, 2007, which is hereby incorporated by reference in its entirety.

### BACKGROUND

This application is directed to photovoltaic solar cell apparatus construction. In particular, it is directed to a photovoltaic cell or module and an associated frame having an integral reflector assembly.

FIG. 1 is a schematic block diagram of a conventional photovoltaic device. A photovoltaic module 10 can typically have one or more photovoltaic cells 12a-b disposed within it. A photovoltaic cell conventionally is made by having a semiconductor junction 14 disposed between a layer of conducting material 19 and a layer of transparent conducting material 16. Light impinges upon the photovoltaic module 10 and transits through the transparent conducting material layer 16. Within the semiconductor, the photons interact with the material to produce electron-hole pairs within the semiconductor junction layer 14. The semiconductor(s) typically is/are doped creating an electric field extending from the junction layer 14. Accordingly, when the holes and/or electrons created by the sunlight in the semiconductor, they will migrate depending on the polarity of the device either to the transparent conducting material layer 16 or the conducting material layer 19. This migration creates current within the cell which is routed out of the cell for storage and/or concurrent use.

One conducting node of the solar cell 12a is shown electrically coupled to an opposite node of another solar cell 12b. In this manner, the current created in one cell may be transmitted to another, where it is eventually collected. The currently depicted apparatus in FIG. 1 is shown where the solar cells are coupled in series, thus creating a higher voltage device. In another manner, (not shown) the solar cells can be coupled in parallel which increases the resulting current rather than the voltage.

FIG. 2 is a schematic block diagram of a photovoltaic apparatus. The photovoltaic apparatus has a photovoltaic panel 20, which contains the active photovoltaic devices, such as those described supra. The photovoltaic panel 20 can be made up of one or multiple photovoltaic cells, photovoltaic modules, or other like photovoltaic devices, singly or multiples, solo or in combination with one another. A frame 22 surrounds the outer edge of the photovoltaic panel that houses the active photovoltaic devices. The frame 22 can be disposed flat or at an angle relative to the plane of the photovoltaic panel 20.

FIG. 3 is a side cross sectional view of the photovoltaic apparatus shown in FIG. 2. In this case, the cross section is taken along the line A-A shown above in FIG. 2. The photovoltaic panel has a photovoltaic device 18 disposed within the frame 22. A glass, plastic, or other translucent barrier 26 is held by the frame 22 to shield the photovoltaic device 18 from an external environment. In some conventional photovoltaic apparatuses, another laminate layer 24 is placed between the photovoltaic device 18 and the translucent barrier 26.

Light impinges through the transparent barrier 26 and strikes the photovoltaic device 18. When the light strikes and is absorbed in the photovoltaic device 18, electricity can be generated much like as described with respect to FIG. 1.

In terms of planar topologies, these geometries are not highly effective in capturing diffuse and/or reflected light, due to their uni-facial makeup (i.e. their ability to capture light emanating from one general direction.) Accordingly, cells or modules that are bifacial (able to capture and convert light from both an “upwards” orientation and a “downwards” orientation) are more effective at utilizing such diffuse or reflected light. In the case of a cylindrical cell or module, these can capture and utilize light from any direction. Accordingly they are labeled as omnifacial devices, and such omnifacial devices are not necessarily strictly limited to those cells or modules having circular cross sections.

Further, these planar topologies are typically characterized by the “sandwich in a sandbox” type frame as depicted above. The planar topologies are also typically characterized with uni-facial collection characteristics. Accordingly, these conventional geometries are not typically used with reflector constructs.

In most conventional planar topologies, the effective area of the active collection area is substantially equivalent to the entire effective area of the panel. This is since the planar topology dictates that the active devices must utilize as much area as possible in their deployment.

In some photovoltaic applications, elongated photovoltaic devices or modules can be arranged in a lattice-like arrangement to collect light radiation and transform that collected radiation into electric energy. In these applications, a generic reflector or albedo surface can be used as a backdrop in conjunction with an elongated solar cell or module, where the reflected, diffuse, or secondary light (i.e. the non-direct path light relative to the source) can be collected, especially when used in conjunction with solar cells or modules that have more than one collection surface (i.e. non-unifacial), or when used with solar cells or modules that are omnifacial in nature (i.e. having a non-planar geometry). However, the geometries of the collection devices are not typically closely tied to the geometries of the reflection devices, resulting in efficiency losses for the associated collection and conversion devices.

Additionally, the planar topologies do not “track” the path of the light source. In order to do this, expensive control and actuation mechanisms would typically be deployed with a planar topology to track the azimuth between the light source and the planar module. This would take time and effort to design, and may require incorporating numerous moving parts that would be prone to breaking.

Further, the use of elongated bifacial solar modules or elongated omnifacial modules is not heavily utilized in the commercial sense. Accordingly, the commercial framing and packaging of large numbers of these types of solar modules has not been heavily emphasized, if at all. Accordingly, the coupling of frames for elongated solar cells with integral reflective constructs simply has not been emphasized in conventional commercial solar activities.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a schematic block diagram of a conventional photovoltaic device.

FIG. 2 is a schematic block diagram of a conventional photovoltaic apparatus.

FIG. 3 is a side cross-sectional view of the photovoltaic apparatus shown in FIG. 2.

FIG. 4 is a perspective view of an exemplary solar panel assembly utilizing concentrators integrated into the frame.

FIG. 5 is a perspective view of the assembly of FIG. 4 without a cross member and detailing the relationship of the frame members, modules, and concentrator.

FIG. 6 is a top view of the assembly of FIG. 4.

FIG. 7 is a cross-sectional view of the assembly of FIG. 6, along the line B-B of FIG. 6.

FIG. 8 is a perspective view of an exemplary unit in a photovoltaic collection system.

FIG. 9 is a cross-sectional view of the unit collection system of FIG. 8, detailing the light capture properties of the collection system.

FIG. 10 is a cross-sectional view detailing the development of the involute of the side of the elongated photovoltaic module.

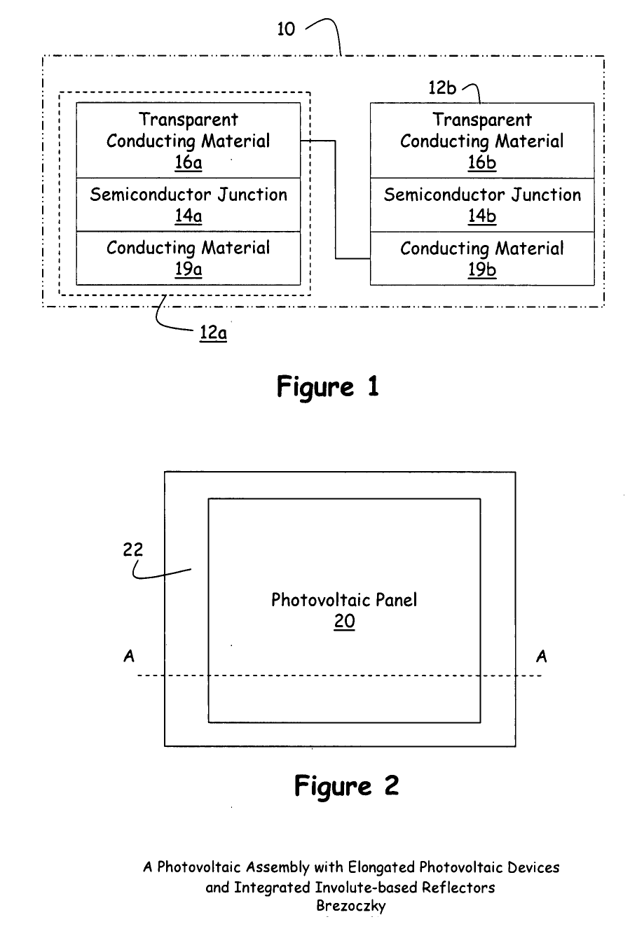

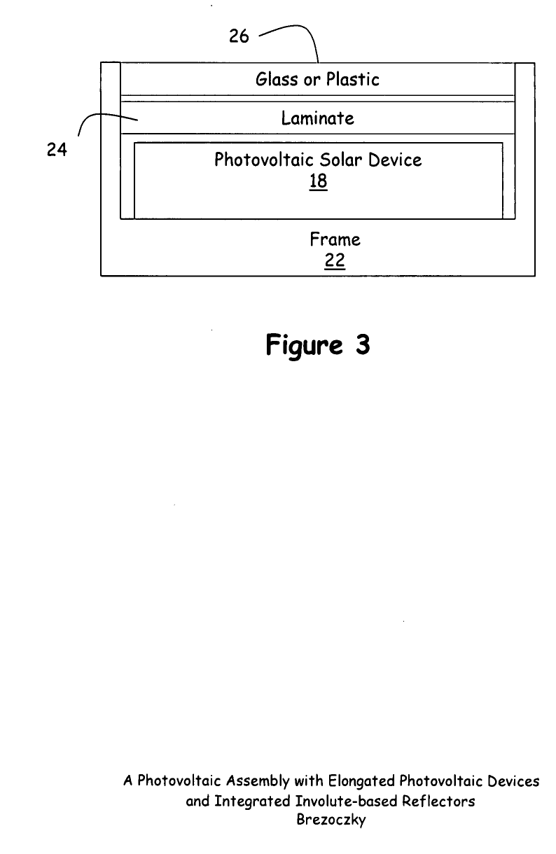

### DETAILED DESCRIPTION

Embodiments of the present invention are described herein in the context of a solar cell architecture having a laminate layer. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

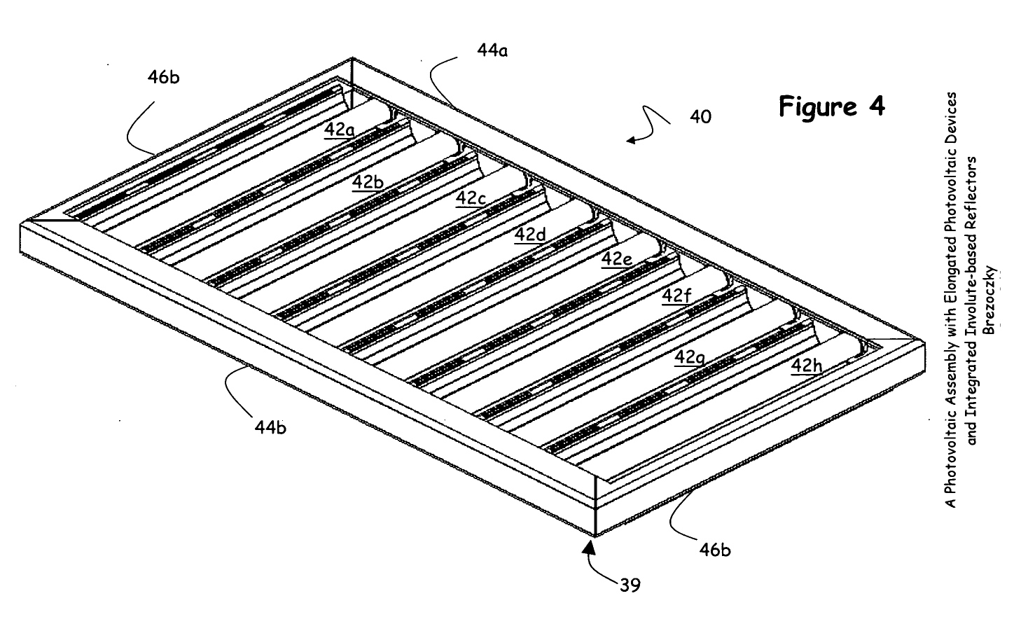

FIG. 4 is a perspective view of a photovoltaic assembly 40 utilizing a concentrator integrated into the frame. The assembly 40 illustrated in FIG. 4 is characterized by having a plurality of photovoltaic modules 42a-h. In other embodiments, assembly 40 has two or more photovoltaic modules 42, 10 or more photovoltaic modules 42, 100 or more photovoltaic modules 42, 1000 or more photovoltaic modules 42, between 2 and 10,000 photovoltaic modules 42, or less than 500 photovoltaic modules 42.

As used in this specification, a photovoltaic module 42 is a device that converts light energy to electric energy, and contains at least one solar cell. A photovoltaic module 42 may be described as an integral formation of a plurality of photovoltaic solar cells, coupled together electrically in an elongated structure. Examples of such photovoltaic modules that include an integral formation of a plurality of photovoltaic cells is found in U.S. patent application Ser. No. 11/378,835, filed Mar. 18, 2006, which is hereby incorporated by reference herein in its entirety. For instance, each photovoltaic cell in an elongated solar module 42 may occupy a portion of an underlying substrate common to the entire photovoltaic module 42 and the cells may be monolithically integrated with each other so that they are electrically coupled to each other either in series or parallel. Alternatively, the elongated photovoltaic module 42 may have one single solar cell that is disposed on a substrate. For the sake of brevity, the current discussion will address the entire photovoltaic structure 42 as a “module”, and it should be understood that this contemplates either a singular elongated solar cell or a series of solar cells disposed along a common elongated non-planar substrate. In some embodiments, a photovoltaic module 42 has 1, 2, 3, 4, 5 or more, 20 or more, or 100 or more such photovoltaic modules. In general, a photovoltaic module 42 is made of a substrate and a material, operable to convert light energy to electric energy, disposed on the substrate. In some embodiments, such material circumferentially coats the underlying substrate. In some embodiments, such material constitutes the one or more solar cells disposed on the substrate. The material typically comprises multiple layers such as a conducting material, a semiconductor junction, and a transparent conducting material.

For purposes of this specification, an elongated photovoltaic module 42 is one that is characterized by having a longitudinal dimension and a width dimension. In some embodiments of an elongated photovoltaic module 42, the longitudinal dimension exceeds the width dimension by at least a factor of 4, at least a factor of 5, or at least a factor of 6. In some embodiments, the longitudinal dimension of the elongated photovoltaic module 42 is 10 centimeters or greater, 20 centimeters or greater, 100 centimeters or greater. In some embodiments, the width dimension of the elongated photovoltaic module 42 is a diameter of 500 millimeters or more, 1 centimeter or more, 2 centimeters or more, 5 centimeters or more, or 10 centimeters or more. The substrate of the module can be rigid in nature. The substrate can be a solid substrate, or a hollow substrate. The substrate can be closed at both ends, only at one end, or open at both ends.

The photovoltaic 42 modules can be characterized by a cross-section bounded by any one of a number of shapes. The shapes can be circular, ovoid, or any shape characterized by smooth curved surfaces, or any splice of smooth curved surfaces. The shapes can also be linear in nature, including triangular, rectangular, pentangular, hexagonal, or having any number of linear segmented surfaces. Or, the cross-section can be bounded by any combination of linear surfaces, arcuate surfaces, or curved surfaces. As described herein, for ease of discussion only, an omnifacial circular cross-section is described in conjunction with the described invention. However, it should be noted that any cross-sectional geometry may be used as an elongated photovoltaic module 42 in the practice.

Referring to FIG. 4, elongated photovoltaic modules 42a-h are disposed within a frame 39. The frame 39 is made up of at least two cross-supports, i.e. cross-support 44a and cross-support 44b. In some embodiments, support 44a and/or support 44b has a plurality of electrical contacts (not shown) arranged along the length of the support. Such electrical contacts may be formed by conducting wires, conducting glue, or any other conducting material useful for drawing current from photovoltaic modules. In some embodiments each of the photovoltaic modules is electrically coupled to an electric contract in the plurality of electric contacts disposed within support 44a and/or support 44b. Because the elongated solar modules 42 are disposed within frame 39, a lattice-like assembly can be constructed. This lattice-like assembly, which comprises one or more photovoltaic assemblies 40 depicted in FIG. 4, can be disposed on a surface to collect light energy and transform that light energy to electric energy. The elongated photovoltaic modules 42a-h in this case are omnifacial (e.g. each have one or more solar cells circumferentially, or partially circumferentially, disposed on a common nonplanar substrate) As used herein, the term solar cells is broadly used to refer to any set of one or more materials that collectively convert light energy to electric energy. Such solar cells typically have a semiconductor junction. Such solar cells are disposed on the surface of the photovoltaic module. Portions of the surface of the photovoltaic module that are occupied by a solar cell are referred to as active surface(s). A distinct advantage of the present invention is that the photovoltaic modules may have, for example, a first active surface that receives direct unreflected light, and one or more second active surfaces that receive light that has been reflected or otherwise redirected from the first and second walls of corresponding concentrator assemblies. Thus, light energy originating from any of multiple different orientations with respect to a cross section of an elongated photovoltaic assembly 42 can strike an active surface of the elongated photovoltaic module 42 in an orthogonal manner. In some embodiments, light energy originating from any orientation with respect to a cross section of an elongated photovoltaic assembly 42 can strike an active surface of the elongated photovoltaic assembly 42 in an orthogonal manner. In some embodiments, a photovoltaic module 42 is omnifacial even when the active zone of the solar cells of the photovoltaic module 42 do not span the complete circumference of the photovoltaic module 42 substrate. In some embodiments, a photovoltaic module 42 is deemed to be omnifacial provided that the active zone of one or more solar cells of the photovoltaic module 42 collectively span at least thirty percent, at least forty percent, at least fifty percent, at least sixty percent, at least seventy percent, at least eighty percent, at least ninety percent, or all of the circumference of the substrate of the elongated photovoltaic module 42. As noted, there may be a single solar cell or a plurality of solar cells spanning the requisite circumference of the substrate of the photovoltaic module 42. As used in this description, photovoltaic modules 42 in which there are a plurality of solar cells spanning the requisite circumference of the substrate are termed “multi-facial” photovoltaic modules because they employ more than one light collecting surface, each oriented in a specific orientation. Further, the elongated photovoltaic modules 42 need not all be omnifacial or multi-facial, and assembly 40 can comprise various combinations of photovoltaic modules 42.

A concentrator is also provided with the frame 39. The concentrator is integrated within the frame 39 such that portions of the concentrator are disposed to the sides and beneath the photovoltaic modules 42a-h. The concentrator can be mechanically attached to the cross-supports 44a and 44b. For example, the cross-supports 44a and 44b can have slots associated with them that allow the concentrator to be inserted and attached to the frame 39.

In FIG. 4, the frame 39 and photovoltaic modules 42a-h do not allow a clear view of the concentrator and its relationship to the photovoltaic modules 42a-h. However, this will be discussed and further described supra.

The concentrator is made of a reflective substance. Thus, light that does not directly strike an active surface of an elongated photovoltaic module 42a-h will strike the concentrator surface integrated with the frame 39. Since the concentrator is reflective, this light will be reflected in the direction of the elongated photovoltaic modules 42a-h.

The concentrator can be made of a specular material, such that a high percentage of the light that strikes the back surface reflectors are again reflected, minimizing retransmission losses. Or, the concentrator can be made with a diffuse material. As will be described later in this specification, the shape of the reflector is designed to reflect the retransmitted light in the direction of a particular elongated photovoltaic module. Advantageously, this can be accomplished without mechanical tracking systems.

The concentrator can be made as a one-piece construction, formed to the appropriate shape. Or, the concentrator can be made up of sub-units, as discussed below.

As depicted in FIG. 4, the frame 39 of the assembly 40 has a lateral support 46a and a lateral support 46b. The reflector can be designed to also fit with the lateral support 46a, the lateral support 46b, or both. It should be noted that while the lateral supports 46a and 46b provide added strength to the solar panel construct, they are optional in nature.

Additionally, it should be noted that the photovoltaic modules 42a-h are shown having an orientation perpendicular to the cross-supports 44a and 44b. It should be noted that the photovoltaic modules 42a-h can have any angular orientation with respect to the cross-supports 44a and 44b, and this description should be construed as implementing any angular orientation between the elongated photovoltaic modules 42a-h and the cross-supports 44a and 44b. For example, each photovoltaic module 42 may intersect a cross-support 44 at an angle other than the perpendicular, such as an obtuse angle and/or an acute angle. Furthermore, as illustrated in FIG. 4, the photovoltaic modules 42 are parallel with respect to each other. While this geometry is contemplated as a preferred embodiment, the disclosure is not limited to such configurations. In some embodiments, the photovoltaic modules 42 are not exactly parallel to each other. In some embodiments, the photovoltaic modules 42 are not parallel to each other. Moreover, as illustrated in FIG. 4, the photovoltaic modules 42 are coplanar. However, the disclosure is not limited to such embodiments. In some embodiments, the photovoltaic modules 42 are positioned at different heights within frame 39, with some being higher in the frame, using the orientation of FIG. 4 where the top of the page is higher than the bottom of the page, as a reference.

As noted previously, the concentrator can be implemented in a single fabricated panel. Or, the concentrator can be made from individual reflectors being coupled together. This is described supra.

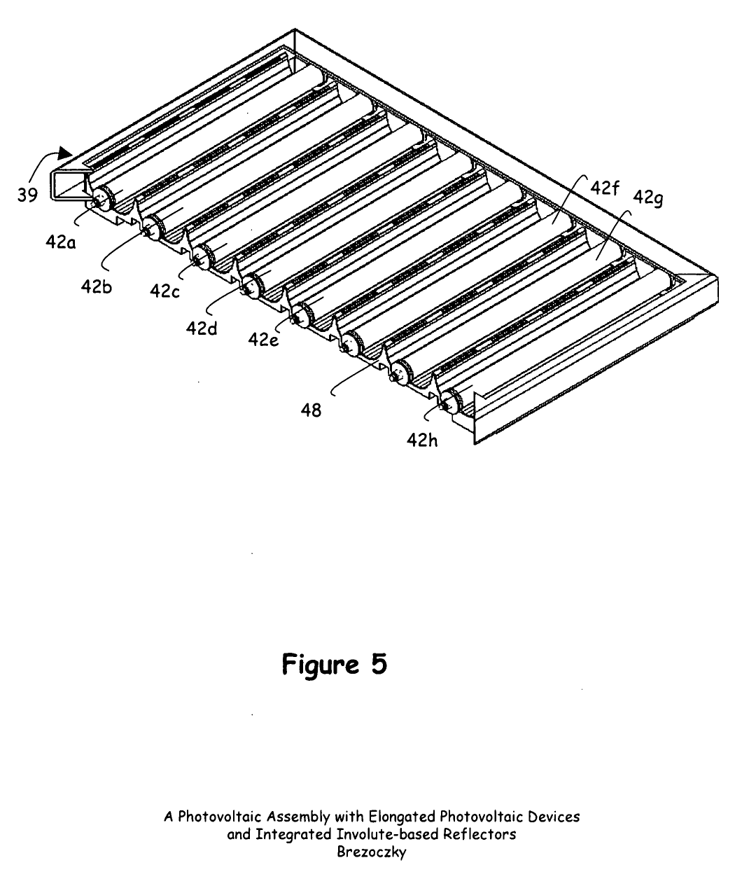

FIG. 5 is a perspective view of the assembly of FIG. 4 without the cross-support 44b and detailing the relationship of the frame members, modules, and concentrator. A concentrator 48 can be seen in FIG. 5. The concentrator 48 has a number of “wells”, where each well is typically defined by a bottom portion and side portions. In an implementation, a respective photovoltaic module from among the photovoltaic modules 42a-h reside in each of these wells, where the concentrator 48 is to the bottom and to each side of each photovoltaic module 42a-h. In this manner, light that does not directly strike a photovoltaic module 42 is redirected (e.g., reflected) from the sides or the bottom portion of concentrator 48 to a particular photovoltaic module 42.

Further, the concentrator 48 can be integrated into the frame 39. In this manner, the frame 39 supports the material making up the concentrator 48, and the concentrator 48 can provide additional lateral stability to assembly 40.

Alternatively, the concentrator 48 can be disposed onto the frame 39. In this manner, the frame 39 supports the weight of the concentrator 48 and the photovoltaic modules 42. This can allow for easy removal of the concentrator 48 for such purposes as elongated photovoltaic module 42 replacement and/or cleaning of a photovoltaic module 42, or for replacement and/or cleaning the concentrator 48 itself

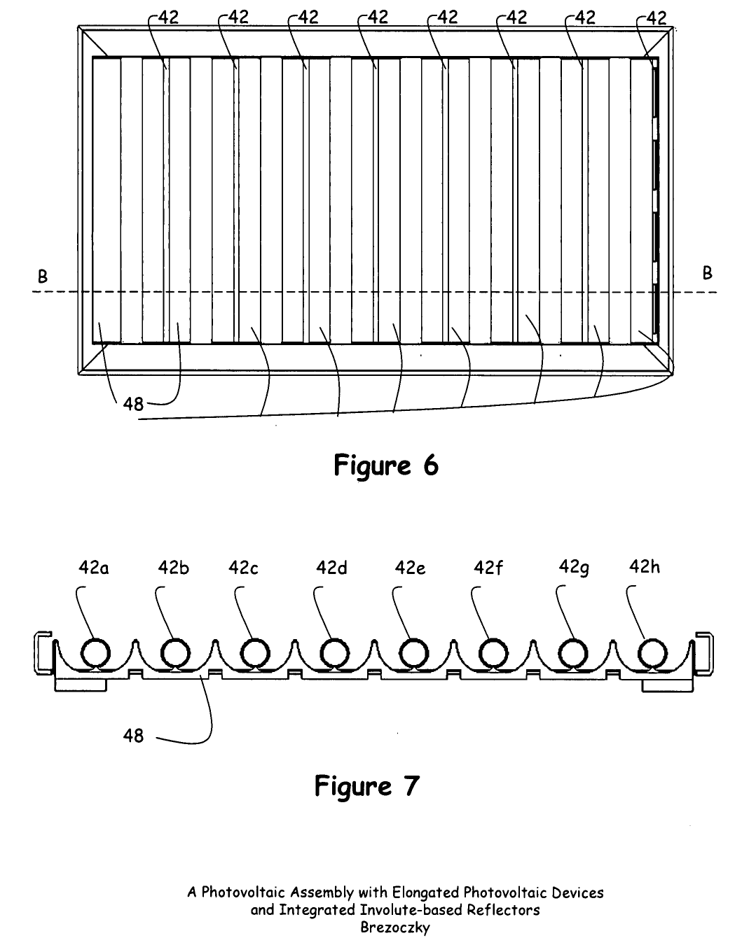

FIG. 6 is a top view of the assembly of FIG. 4. In this Figure, the photovoltaic modules 42 are shown spaced apart from one another. The spaces between the photovoltaic modules 42 are shown to be “filled” with the concentrator 48, such that a substantial proportion of light that impinges on the area of the assembly 40 is directed to the photovoltaic modules 42a-h.

FIG. 7 is a cut-away view of the assembly of FIG. 6, along the line B-B of FIG. 6. FIG. 7 shows some of the geometric relationships between the photovoltaic modules 42a-h and the concentrator 48 in accordance with an embodiment in which the photovoltaic modules 42 run substantially parallel with respect to each other and are substantially co-planar.

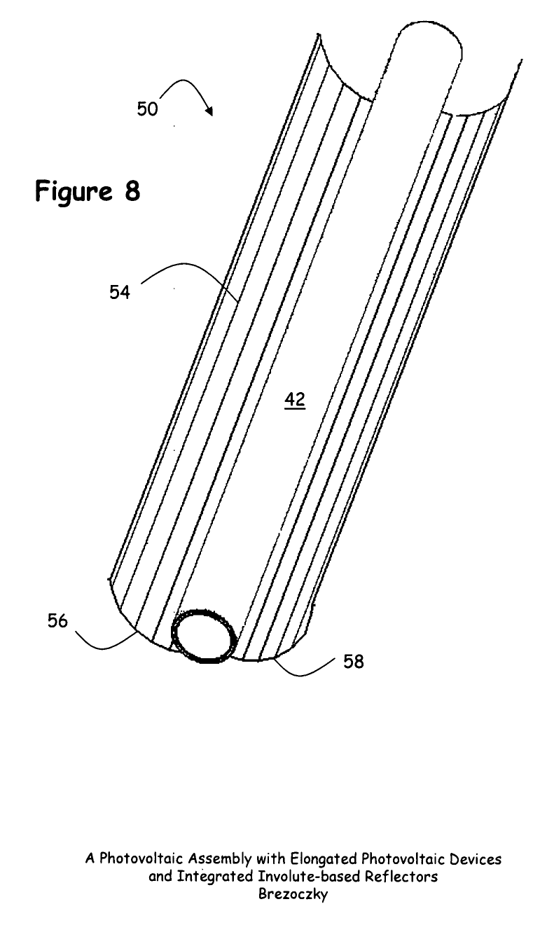

FIG. 8 is a perspective view of an exemplary single module-concentrator unit of the assembly 40 of FIG. 4. The single module-concentrator unit is a form of a concentrator assembly 54. A photovoltaic module 42 is associated with a concentrator assembly 54. In some embodiments, the concentrator 48 of FIGS. 5, 6, and 7 can be made up of a first number (e.g., a plurality) of concentrator assemblies 54 of FIG. 8. In some such embodiments, individual concentrator assemblies 54 run parallel or approximately parallel to each other without touching. In other such embodiments, concentrator assemblies 54 are formed into a larger integral structure, where the larger integral structure is referred to, in those such embodiments, as the concentrator 48.

A concentrator assembly 54 generally forms a concave surface or a surface that can be approximated as concave, in which the photovoltaic module 42 is disposed. The concentrator assembly 54 is typically made of non-absorbing or low-absorbing material with respect to light energy. In one embodiment, the concentrator assembly 54 can be made with a specular or reflective material, such that a high proportion of light energy striking it is reflected (as opposed to absorbed).

The concentrator assembly 54 is made of a first wall 56 and a second wall 58. Each wall bounds an opposite side of the included elongated photovoltaic module 42. In the embodiment depicted, the wall 56 ends at a point tangent or substantially tangent to the height (topmost portion) of the photovoltaic module 42. In a similar manner, the wall 58 ends at a point tangent or substantially tangent to the height (topmost portion) of the photovoltaic module 42.

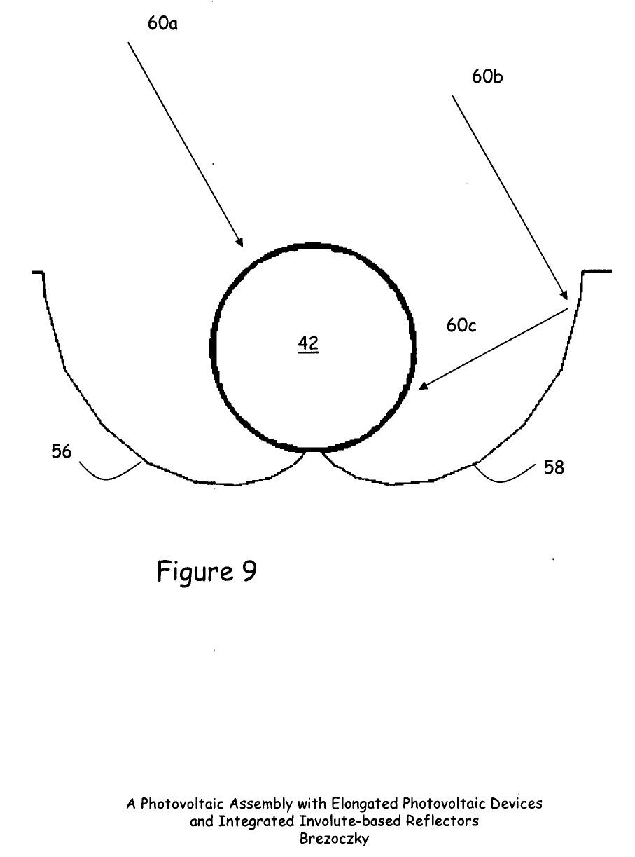

FIG. 9 is a cross-sectional view of the collection system 50 of FIG. 8, detailing the light capture properties of the collection system 50. In the photovoltaic collection system 50, the light from a source approaches the opening defined by the walls 56 and 58, and enters into an interior defined by the same walls 56 and 58. A light ray 60a enters the photovoltaic collection system and directly strikes the photovoltaic module 42, where it is absorbed and converted to electric energy. Another light ray 60b enters the photovoltaic collection system and strikes the wall 58. The wall 58 redirects light ray 60b, thereby forming redirected (reflected) light ray 60c. The light ray 60c ultimately strikes the photovoltaic module 42, albeit from a direction other than the direction it originally entered the collection system.

Thus, the system as depicted can produce electric energy from light that directly strikes the photovoltaic module 42 from the initial source. Further, the system as depicted can produce electric energy from light that is not necessarily directed at the forward face of the photovoltaic module 42. This is advantageous, because, as noted in the background section, conventional photovoltaic collection designs are typically limited to the use of light directed at the forward face of the solar panel. Further, embodiments where photovoltaic module 42 has multiple light energy collection and/or conversion areas (e.g., multiple solar cells, or active areas facing away from the forward face), thus allowing redirected light to be collected and transformed on the side facing of the module, the back facing of the module, or both. In this manner, diffuse light collection and transformation can be substantially improved.

In some embodiments, the shape of the walls 56 and 58 are defined as involutes or substantially the involutes of the sides of the photovoltaic module 42. An involute is a shape that is dependent upon the shape of another object, where that object is made up of substantially smooth curves, or from a series of faces that approximate a smooth curve. It will be appreciated that the walls 56 and 58 may be separate pieces. In alternative embodiments, the walls 56 and 58 may be molded as a single piece. In such embodiments, the single piece includes the involute sections 56 and 58 with a connector section that joins the two sections together, thereby forming a single piece.

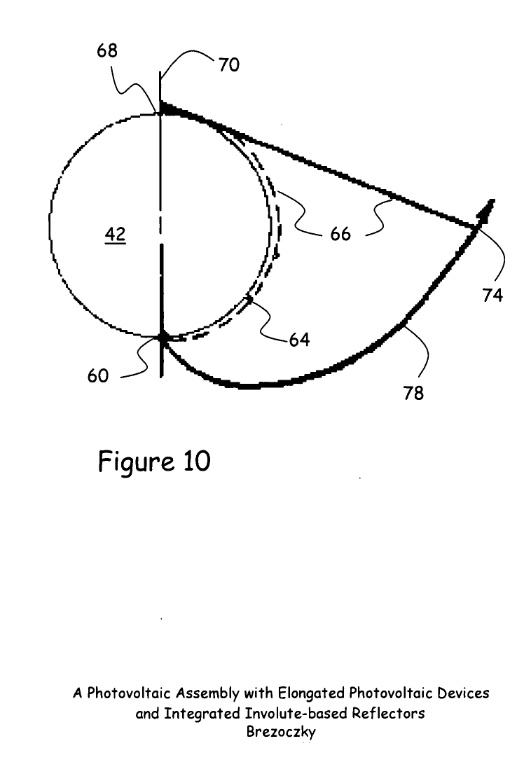

FIG. 10 is a cut-away view detailing the development of the involute of the side of photovoltaic module 42. In FIG. 10, the photovoltaic module 42 is shown having the same circular cross-section as the photovoltaic module depicted in FIGS. 8 and 9. The involute of a side 64 of the elongated photovoltaic module 42 is formed as follows. A fixed point 68 of the elongated photovoltaic module 42 is defined to be the topmost point of the cross-section of the elongated photovoltaic module 42. A fixed point 68 lies on a reference axis 70, and the reference axis 70 includes a point 60 on the elongated photovoltaic module 42. A point 60 corresponds to the point that the elongated photovoltaic module 42 rests on the juncture of walls 56 and 58. An imaginary thread 66 is fastened to photovoltaic module 42 at point 68, where the length of the imaginary thread 66 is defined as half of the circumference of the circular cross section of the photovoltaic module 42.

Assume that thread 66 is wrapped around the photovoltaic module 42 in a clockwise direction and held taut. The locus of the end 74 of the thread 66 as it is wrapped (or unwrapped) from the elongated photovoltaic module 42 defines a curve 78 of FIG. 10, and is the involute of the side 64 of the photovoltaic module 42. The side 64 is the portion of module 42 that corresponds to curve 78, and hence is the evolute of the curve 78. The curve 78 of FIG. 10 corresponds to substantially the shape of the wall 58 of FIGS. 8 and 9.

Correspondingly, the shape of the wall 56 is determined in a substantially similar manner, but with the direction of the wrapping of the thread 66 being oriented in a counter-clockwise orientation beginning at point 68. In some embodiments, as depicted in FIGS. 8 and 9, the walls 56 and 58 tangentially touch module 42 on the side of the module 42 that faces away from direct light. However, it will be appreciated that there is no requirement for the walls 56 and 58 to contact the module 42 in order to form the involute of the sides of the module 42. Although a curve has a unique evolute, it has infinitely many involutes corresponding to different choices of initial and final points. Thus, consider the case where the initial point of the involute curve 78 is as discussed for FIG. 10, point 68, but the final point of the curve 78 is reached at some point before curve 78 touches the module 42 at point 60. Such a curve is still the involute of the module 42 and is within the scope of the present disclosure. In some embodiments, the walls 56 and 58 are limited by the height h of the module 42 but are not involute as they approach the bottom of module 42 in the vicinity of the point 60 of FIG. 10. In some instances, a joinder piece that is not the involute of any surface of the module 42 joins the walls 56 and 58 together and supports the module 42 in the vicinity of the point 60. In some embodiments, this joinder (not shown), and the involute portions of the walls 56 and 58 are a single integrated piece. In some embodiments, the joinder includes a groove that is complementary to the shape of the bottom portion of the module 42. For example, in some embodiments, the module 42 is cylindrical and the joinder includes a groove into which a bottom portion of module 42 fits.

The results from the involute topology described in conjunction with FIGS. 8-10 is that a substantial proportion of the light entering the area delineated between walls 56 and 58 is eventually directed (e.g. reflected) onto the elongated photovoltaic modules 42. Thus the effective area of the elongated photovoltaic modules 42 is dramatically increased.

In terms of the geometry, the involute is especially efficient in transmitting reflected light. In particular, when one uses the involute of the base shape of the photovoltaic module with the photovoltaic module 42, this will cause a light ray impinging on any portion of the involute reflector to eventually be transmitted to the elongated photovoltaic module 42. Thus, there is an extraordinarily high proportion of the light impinging into the area defined between the tops of the walls 56 and 58 that reaches the photovoltaic module 42 when using the involute shape reflector.

In this particular case (e.g. the cross section of the photovoltaic module being a circle), the surface of the concentrator 54 can be categorized as having substantially the shape defined in the x and y coordinate system depicted on FIG. 9. The equation describing the reflecting surface in the coordinate system can be described in equations (1) and (2), below:

x=a(cos(α)+α sin(α)); (1)

y=a(cos(α)−α sin(α)); (2)

where α is a particular angle rotation about the module 42, and a is the radius of the module 42. This applies to each wall as specified with the proper turning direction.

In constructing a reflector for use in a practical application, the involute need not extend vertically a substantial distance. In fact, the involute is best limited to having a side wall only as high as the topmost portion of the photovoltaic module 42, using the orientations of FIG. 10 for reference, or having a rotation angle of the involute extending ½ of the diameter around the circular cross-section as noted. This orientation provides two advantages. First, shadowing of the elongated photovoltaic module 52 would be increased if the vertical wall extended more than the topmost level of the elongated photovoltaic module 52. This is since the involute, if extended to this angle, would actually begin to bend inward over the top portion of the elongated photovoltaic module 42. Second, this limitation limits the amounts of material used in the construction of the walls 56 and 58. This saves time, money, and fabrication expenses to provide the particular concentrator 54.

In some cases, the height at which the reflector surface ends corresponds to the topmost portion of the photovoltaic module 42 using the orientations of FIG. 9 for reference. In another case, the height at which the concentrator 54 surface ends corresponds to a point that exceeds the height of the topmost portion of the photovoltaic module 42 by up to 10% of the total height h of the module 42 using FIG. 9 for reference. In some embodiments the side of the concentrator 54 ends at a height corresponding the to the midpoint diameter of the module 42 in embodiments where the module 42 is cylindrical or approximately cylindrical. Other potential ending heights for the side of the concentrator 54 can also be d/2, d/4, 3d/4, 3d/8, 5d/8, 7d/8, 5/16d, 7/16d, 9d/16, 11d/16, 13d/16, and 15d/16, where d is the height h of the photovoltaic module 42 as illustrated in FIG. 9. Any height between d/2 and d can be thought of as providing very good energy conversion ratios. One should note that the height h of concentrator 54 can be any height. Moreover, in some embodiments, only a portion of the wall 56 and/or wall 58 forms the involute of a corresponding evolute of the module 42. For example, if the wall 56 and/or wall 58 is considered in terms of the curve swept out by the respective wall as illustrated, for example by curve 78 of FIG. 10, in some embodiments, fifty percent or more of the curve swept out by wall 56 and/or wall 58 is an involute of a corresponding evolute of the module 42. In some embodiments, sixty percent or more, seventy percent or more, eighty percent or more, ninety percent or more, or the entire curve swept out by the wall 56 and/or wall 58 is an involute of a corresponding evolute of the module 42. The balance of the curve swept out by wall 56 and/or 58 in such embodiments can adopt any shape that will facilitate the function of the concentrator 54, either in its role as a concentrator, or in an auxiliary role as a physical support for the module 42, to link together different concentrator assemblies, to link the concentrator into the frame, or to further physically integrate the module 42 into a planar array of modules.

In one embodiment, a series of elongated solar modules 42 are envisioned, each with a corresponding involute-based concentrator 54. Each structure is arranged in parallel. Accordingly, light that would otherwise be channeled to the photovoltaic module 42 by an extended side of the reflector is instead captured by a neighboring concentrator/photovoltaic module structure. It should be noted that the photovoltaic module depicted need not be cylindrical in nature. In fact, the photovoltaic module needs only have bifacial or omnifacial characteristics to enjoy the benefits of the involute concentrator. Correspondingly, the concentrator should be constructed as the involute (or proportion of an involute shape) of whatever shape the photovoltaic module might be. Accordingly, any cross-sectional geometry of the photovoltaic module 42 is envisioned, and any involute of such a cross section is envisioned that coordinates with the particular module cross-section.

In some embodiments, (as noted previously) the walls 56 and 58 may not be wholly an involute shape. As has been described, the walls can deviate from the involute shape in order to achieve some other engineering function. For example, a mechanical joint can be added to the end of the wall 56, such that the mechanical joint is able to latch or otherwise attach to some retaining device, such as a frame. Thus, the full proportion of wall 56 need not wholly conform to the involute shape.

When the wall 56 of the concentrator 54 stands at the level of the topmost portion of the elongated photovoltaic module 42 as illustrated in FIG. 9, and the cross section of the photovoltaic module is circular, the distance between the topmost portion of the photovoltaic module 42 and the wall 56 is c/2, where c is the circumference of the included photovoltaic module 42, or in other words πd/2, where d is the diameter of the circular cross section of a cylindrical photovoltaic module 42. Thus, when two constructs are placed in parallel, the distance between the midpoints of adjoining photovoltaic modules is 2*(πd)/2, or simply πd. The distance between the edges of adjoining photovoltaic modules 42 is 2*(π−1)*d. Of course, this is when the involutes are in a strict side-to-side touching mode. One could introduce a thickness to the top edge of the wall, introducing more distance between the individual involute—module structures.

The active effective area engaged in solar collection and conversion is the area bounded by the two elongated photovoltaic modules, which is proportional to 2d. The total area of the two collection systems is proportional to 2πd. Thus, the ratio of total effective collection area to effective active collection and conversion area is 2πd:2d, or simply π:1.

The composition of the concentrator assembly 54 surface (i.e. walls 56 and wall 58) is a specular material in preferred embodiments. Material with high specular characteristics is desired, since this will reduce reflection loss. In this manner, the walls 56 and 58 can be manufactured from such materials as aluminum or aluminum alloy. In another embodiment, the material can be one that is diffuse.

In one embodiment, concentrator assembly 54 is made as a thin panel of a reflective material overlaid on a substrate or mold. In one embodiment, the concentrator assembly is made as a single sheet of material. In another embodiment, the concentrator assembly 54 is made of, or machined from, a single block of the reflective material.

In another embodiment, concentrator assembly 54 can be made of a substrate coated with specular material. For example, concentrator assembly 54 could be made as a substrate of a plastic, and then coated with a specular material such as aluminum. In some cases, the specular material is polished to enhance the reflective properties. Or, the material is coated with a sealant to preserve the specular properties, especially when the specular material is polished.

In context, the one or more solar cells that are on the above-described photovoltaic units 42 can be made of various materials, and in any variety of manners. Examples of compounds that can be used to produce the solar cells can include Group IV elemental semiconductors such as: carbon (C), silicon (Si) (both amorphous and crystalline), germanium (Ge); Group IV compound semiconductors, such as: silicon carbide (SiC), silicon germanide (SiGe); Group III-V semiconductors, such as: aluminum antimonide (AlSb), aluminum, arsenide (AlAs), aluminum nitride (AlN), aluminum phosphide (AlP), boron nitride (BN), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP); Group III-V ternary semiconductor alloys, such as: aluminum gallium arsenide (AlGaAs, AlxGa1−xAs), indium gallium arsenide (InGaAs, InxGa1−xAs), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb); Group III-V quaternary semiconductor alloys, such as: aluminum gallium indium phosphide (AlGalnP, also InAlGaP, InGaAIP, AlInGaP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN); Group III-V quinary semiconductor alloys, such as: gallium indium nitride arsenide antimonide (GaInNAsSb); Group II-VI semiconductors, such as: cadmium selenide (CdSe), cadmium sulfide (CdS), cadmium telluride (CdTe), zinc oxide (ZnO), zinc selenide (ZnSe), zinc sulfide (ZnS), zinc telluride (ZnTe); Group II-VI ternary alloy semiconductors, such as: cadmium zinc telluride (CdZnTe, CZT), mercury cadmium telluride (HgCdTe), mercury zinc telluride (HgZnTe), mercury zinc selenide (HgZnSe); Group I-VII semiconductors, such as: cuprous chloride (CuCl); Group IV-VI semiconductors, such as: lead selenide (PbSe), lead sulfide (PbS), lead telluride (PbTe), tin sulfide (SnS), tin telluride (SnTe); Group IV-VI ternary semiconductors, such as: lead tin telluride (PbSnTe), thallium tin telluride (Tl₂SnTe₅), thallium germanium telluride (Tl₂GeTe₅); Group V-VI semiconductors, such as: bismuth telluride (Bi₂Te₃); Group II-V semiconductors, such as: cadmium phosphide (Cd₃P₂), cadmium arsenide (Cd₃As₂), cadmium antimonide (Cd₃Sb₂), zinc phosphide (Zn₃P₂), zinc arsenide (Zn₃As₂), zinc antimonide (Zn₃Sb₂); layered semiconductors, such as: lead(II) iodide (Pbl₂), molybdenum disulfide (MOS₂), gallium selenide (GaSe), tin sulfide (SnS), bismuth sulfide (Bi₂S₃); others, such as: copper indium gallium selenide (CIGS), platinum silicide (PtSi), bismuth(III) iodide (BiI3), mercury(II) iodide (Hgl₂), thallium(I) bromide (TIBr); or miscellaneous oxides, such as: titanium dioxide anatase (TiO₂), copper(I) oxide (Cu₂O), copper(II) oxide (CuO), uranium dioxide (UO₂), or uranium trioxide (UO₃). This listing is not exclusive, but exemplary in nature. Further, the individual grouping lists are also exemplary and not exclusive. Accordingly, this description of the potential semiconductors that can be used in the solar cells of the photovoltaic units 42 should be regarded as illustrative.

The foregoing materials may be used with various dopings to form a semiconductor junction. For example, a layer of silicon can be doped with an element or substance, such that when the doping material is added, it takes away (accepts) weakly-bound outer electrons, and increases the number of free positive charge carriers (e.g. a p-type semiconductor.) Another layer can be doped with an element or substance, such that when the doping material is added, it gives (donates) weakly-bound outer electrons addition and increases the number of free electrons (e.g. an n-type semiconductor.) An intrinsic semiconductor, also called an undoped semiconductor or i-type semiconductor, can also be used. This intrinsic semiconductor is typically a pure semiconductor without any significant doping. The intrinsic semiconductor, also called an undoped semiconductor or i-type semiconductor, is a pure semiconductor without any significant dopants present. The semiconductor junction layer can be made from various combinations of p-, n-, and i-type semiconductors, and this description should be read to include those combinations.

The solar cells of the elongated photovoltaic modules 42 may be made in various ways and have various thicknesses. The solar cells as described herein may be so-called thick-film semiconductor structures or a so-called thin-film semiconductor structures.

An assembly for converting light energy to electric energy has a first number of photovoltaic modules. Each of the photovoltaic modules has a substrate and material disposed on the substrate. The material is operable to convert light energy to electric energy. Each of the photovoltaic modules is characterized by having a longitudinal dimension and a cross-sectional dimension, and the longitudinal dimension is typically greater that four times the cross-sectional dimension. A concentrator is provided that has a first number of concentrator assemblies. Each of the concentrator assemblies is associated with a particular photovoltaic module. Each of the concentrator assemblies has a first surface and a second surface. The first surface and the second surface form a concave structure, and the first surface and the second surface are operable to transmit (e.g., reflect) light energy that enters the concave structure to an associated photovoltaic module. The first and second surface have substantially the shape of the involute of the photovoltaic module associated with the concentrator assembly. The first and second surface typically extend no more than the height of the associated photovoltaic module. The assembly also has a frame with a first and second support. Each of the photovoltaic modules extends from the first support to the second support and is electrically coupled to an electric contact disposed within the first support. The concentrator is mechanically attached to the frame.

An assembly for converting light energy to electric energy has a first number of means for converting light energy to electric energy. Each of the first number of means for converting can be characterized as having a longitudinal dimension and a cross-sectional dimension. The longitudinal dimension can typically be greater that four times the cross-sectional dimension. The means for converting can be characterized by having an inside longitudinal boundary and an opposing outside longitudinal boundary. Also included are means for concentrating light energy onto each of the first number of means for converting. The means for concentrating typically extend no more than the height of an associated means for converting. A means for supporting is included. The means for supporting supports the means of converting and supports the means for concentrating in a particular fixed orientation. An outside edge of a first means for converting is disposed from an inside edge of an adjacent second means for converting by at least the cross-sectional dimension of the means for converting. The means for converting resides above a portion of the means for concentrating. A portion of the means for concentrating is disposed between the inside edge of the second means for converting and the outside edge of the first means for converting.

An assembly for producing electric energy from light energy has a first frame member having a length L. A second frame member is oriented substantially parallel to the first frame member and disposed from the first frame member by a distance D, the distance D is typically smaller than the length L. A concentrator is provided. The concentrator is made of a reflective material. A plurality of concentrator assemblies is associated with the concentrator. A concentrator assembly has a first surface having a first surface edge and second surface having a second surface edge. The first surface and the second surface form a concave-shaped structure having an opening defined by the first surface edge and the second surface edge. The opening is operable to admit light into the concave-shaped structure. Elongated photovoltaic modules are provided. An elongated photovoltaic module is typically characterized by a first area facing the opening and a second area facing a second direction. The second direction is faces a different direction than the top area. An elongated photovoltaic module is made of a rigid substrate and one or more layers of photovoltaic material disposed upon the substrate. The photovoltaic material converts light that impinges upon it to electric energy. The elongated photovoltaic module is able operable to concurrently: a) produce electric energy from light directly striking the top area of the elongated photovoltaic module; and b) produce electric energy from light redirected by a concentrator assembly to the second area. A first elongated photovoltaic module is typically associated with a first concentrator assembly from the plurality of concentrator assemblies. The first photovoltaic module resides within the concave-shaped structure associated with the first concentrator assembly, and has an outer edge in the direction of the opening defined by the first concentrator assembly. The first surface of the first concentrator assembly is at least in part an involute of the first photovoltaic modules. The second surface of the first concentrator assembly is at least in part an involute of the first photovoltaic modules. The outer edge of a photovoltaic module is at least as high as the first surface edge. The outer edge of the first photovoltaic module is at least as high as the second surface edge.

An assembly for converting light energy to electric energy has a first number of photovoltaic modules. The photovoltaic modules have a substrate and photovoltaic material disposed on the substrate. The photovoltaic material is operable to convert light energy to electric energy. The photovoltaic modules have a longitudinal dimension and a cross-sectional dimension, where the longitudinal dimension is typically greater than four times the cross-sectional dimension. A concentrator is provided. The concentrator has a first number of concentrator assemblies, where each of the concentrator assemblies is associated with a particular photovoltaic module. A concentrator assembly has a fixed first surface and a fixed second surface made at least in part from a reflective material. The first surface and the second surface form a concave structure, and the first surface and the second surface can transmit light energy that enters the concave structure to a photovoltaic module. The first surface has a portion shaped as an involute of the photovoltaic module associated with the particular concentrator assembly. The second surface has a portion shaped as an involute of the photovoltaic module associated with the particular concentrator assembly. The first surface and the second surface typically extend no more than the height of the photovoltaic module associated with the concentrator assembly. A frame is also provided. The frame has a first support and a second support. The photovoltaic modules extend from the first support to the second support. Each of the photovoltaic modules can be electrically coupled to an electric contact disposed within the first support. The concentrator can be mechanically attached to the frame. A substantial portion of light striking a concentrator assembly is ultimately redirected to a photovoltaic module.

The substrate of a photovoltaic module can be a rigid substrate. Rigidity of a material can be measured using several different metrics including, but not limited to, Young's modulus. In solid mechanics, Young's Modulus (E) (also known as the Young Modulus, modulus of elasticity, elastic modulus or tensile modulus) is a measure of the stiffness of a given material. It is defined as the ratio, for small strains, of the rate of change of stress with strain. This can be experimentally determined from the slope of a stress-strain curve created during tensile tests conducted on a sample of the material. Young's modulus for various materials is given in the following table.

| | Young's | |
|---|---|---|
| | modulus (E) in | Young's modulus |
| Material | GPa | (E) in lbf/in² (psi) |
| Rubber (small strain) | 0.01-0.1 | 1,500-15,000 |
| Low density polyethylene | 0.2 | 30,000 |
| Polypropylene | 1.5-2 | 217,000-290,000 |
| Polyethylene terephthalate | 2-2.5 | 290,000-360,000 |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced | 150 | 21,800,000 |
| plastic (unidirectional, | | |
| along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments of the present application, a material (e.g., a substrate) is deemed to be rigid when it is made of a material that has a Young's modulus of 20 GPa or greater, 30 GPa or greater, 40 GPa or greater, 50 GPa or greater, 60 GPa or greater, or 70 GPa or greater. In some embodiments of the present application a material (e.g., a substrate) is deemed to be rigid when the Young's modulus for the material is a constant over a range of strains. Such materials are called linear, and are said to obey Hooke's law. Thus, in some embodiments, the substrate is made out of a linear material that obeys Hooke's law. Examples of linear materials include, but are not limited to, steel, carbon fiber, and glass. Rubber and soil (except at very low strains) are non-linear materials. Hence, materials that are only linear at such low strains are deemed to not be linear materials in the present application. The substrate can be a hollow substrate.

The photovoltaic module can have a circular cross-section. The photovoltaic module can have a length in the longitudinal dimension of at least 400 cm.

A concentrator assembly can be a specular material. The concentrator assembly can be made of a material no more than 20 cm thick. A concentrator assembly can be made of a reflective material disposed on a concentrator substrate. A concentrator assembly can be made with a plastic. A concentrator assembly can have a substrate that is made with a polymer. A concentrator assembly can have a substrate that is made with a metal. A concentrator assembly can be made with a ceramic. A concentrator assembly can be made with an integrally formed mass of material. A concentrator assembly can be a reflective material with a sealant disposed on the reflective material.

The concentrator can be a first concentrator assembly and a second concentrator assembly joined with a mechanical link.

The first surface and the second surface of a concentrator assembly can be joined at a junction, and the associated photovoltaic module can be disposed on the junction in touching relationship with the junction. The photovoltaic module can also be disposed between the first surface and the second surface and above the junction.

The assembly frame can be made with a first longitudinal support and a second longitudinal support. The first longitudinal support can be coupled to the first support at one end of the first support and also coupled to the second support at the same end of the second support. The second longitudinal support can be coupled to the first support at the opposite end of the first support and coupled to the second support at the opposite end of the second support.

The plurality of photovoltaic modules can be coupled to the first support between the first and second longitudinal support. The photovoltaic modules can be coupled to the second support between the first longitudinal support and the second longitudinal support.

The concentrator can be mechanically coupled to the first longitudinal support. The concentrator can be coupled to the top of the first longitudinal support.

The photovoltaic modules can be substantially perpendicular to the first support and to the second support.

Thus, a photovoltaic assembly with elongated photovoltaic devices and integrated involute-based reflectors is described and illustrated. Those skilled in the art will recognize that many modifications and variations of the present invention are possible without departing from the invention. Of course, the various features depicted in each of the figures and the accompanying text may be combined together.

Accordingly, it should be clearly understood that the present invention is not intended to be limited by the particular features specifically described and illustrated in the drawings, but the concept of the present invention is to be measured by the scope of the appended claims. It should be understood that various changes, substitutions, and alterations could be made hereto without departing from the spirit and scope of the invention as described by the appended claims that follow.

We claim:

1. An assembly for converting light energy to electric energy, the assembly comprising:
a first number of photovoltaic modules, each of the first number of photovoltaic modules comprising:
a substrate;
a material disposed on the substrate operable to convert light energy to electric energy;
each of the first number of photovoltaic modules characterized by having a longitudinal dimension and a cross-sectional dimension, the longitudinal dimension being greater than four times the cross-sectional dimension;
a concentrator having a first number of concentrator assemblies, each of the first number of concentrator assemblies associated with a particular photovoltaic module from the first number of photovoltaic modules, each respective concentrator assembly of the first number of concentrator assemblies comprising:
a first surface and a second surface, the first surface and the second surface forming a concave structure operable to transmit light energy that enters the concave structure to the associated particular photovoltaic module;
the first surface and the second surface each comprising substantially the shape of the involute of the particular photovoltaic module associated with the respective concentrator assembly;
the first surface and the second surface extending no more than the height of the particular photovoltaic module associated with the respective concentrator assembly;
a frame comprising:
a first support with a plurality of electric contacts disposed therein; and
a second support;
each of the first number of photovoltaic modules extending from the first support to the second support;
each of the first number of photovoltaic modules electrically coupled to an electric contact in the plurality of electric contacts disposed within the first support; and
the concentrator being mechanically attached to the frame.

2. The assembly of claim 1 wherein the substrate of a photovoltaic module in the first number of photovoltaic modules is a rigid substrate.

3. The assembly of claim 1 wherein the substrate of a photovoltaic module in the first number of photovoltaic modules has a Young's modulus of 20 GPa or greater.

4. The assembly of claim 1 wherein the substrate of a photovoltaic module in the first number of photovoltaic modules has a Young's modulus of 40 GPa or greater.

5. The assembly of claim 1 wherein the substrate of a photovoltaic module in the first number of photovoltaic modules has a Young's modulus of 70 GPa or greater.

6. The assembly of claim 1 wherein the substrate of a photovoltaic module in the first number of photovoltaic modules is a hollow substrate.

7. The assembly of claim 1 wherein a photovoltaic module in the first number of photovoltaic modules has a circular cross-section.

8. The assembly of claim 1 wherein a photovoltaic module in the first number of photovoltaic modules has a length in the longitudinal dimension of at least 400 cm.

9. The assembly of claim 1 wherein the first surface and the second surface of a concentrator assembly in the first number of concentrator assemblies comprises a specular material.

10. The assembly of claim 1 wherein the first surface and the second surface of a concentrator assembly in the first number of concentrator assemblies comprises a material that is no more than 20 cm thick.

11. The assembly of claim 1 wherein the first surface and the second surface of a concentrator assembly in the first number of concentrator assemblies comprises a reflective material disposed on a concentrator assembly substrate.

12. The assembly of claim 11 wherein the concentrator assembly substrate comprises a plastic.

13. The assembly of claim 11 wherein the concentrator substrate assembly comprises a polymer.

14. The assembly of claim 11 wherein the concentrator substrate assembly comprises a metal.

15. The assembly of claim 11 wherein the concentrator substrate assembly comprises a ceramic.

16. The assembly of claim 1 wherein the concentrator comprises a first concentrator assembly and a second concentrator assembly joined with a mechanical link.

17. The assembly of claim 1 wherein the concentrator consists of an integrally formed mass of material.

18. The assembly of claim 1 wherein the first surface and the second surface of a concentrator assembly in the first number of concentrator assemblies comprises a reflective material and a sealant disposed on the reflective material.

19. The assembly of claim 1 wherein the first surface and the second surface of a concentrator assembly in the first number of concentrator assemblies are joined at a junction, and a photovoltaic module in the first number of photovoltaic modules that is associated with the concentrator assembly is disposed on the junction in touching relationship with the junction.

20. The assembly of claim 1 wherein the first surface and the second surface of a concentrator assembly in the first number of concentrator assemblies are joined at a junction, and a photovoltaic module in the first number of photovoltaic modules that is associated with the concentrator assembly is disposed between the first surface and the second surface of the concentrator assembly and above the junction.

21. The assembly of claim 1, the frame further comprising:
a first longitudinal support coupled to the first support at a first point at a first end of the first support and to the second support at a second point at a first end of the second support; and
a second longitudinal support coupled to the first support at a third point at an opposite end to the first end of the first support and to the second support at a fourth point at an opposite end to the first end of the second support.

22. The assembly of claim 21 wherein
the first number of photovoltaic modules is coupled to the first support at a corresponding first number of points disposed along the first support, the first number of points disposed along the first support being between the first point and the third point; and
the first number of photovoltaic modules is coupled to the second support at a corresponding second number of points disposed along the second support, the second number of points disposed along the second support being between the second point and the fourth point.

23. The assembly of claim 21 wherein the concentrator is mechanically coupled to the first longitudinal support.

24. The assembly of claim 21 wherein the concentrator is mechanically coupled to the top of the first longitudinal support.

25. The assembly of claim 1 wherein the first number of photovoltaic modules is substantially perpendicular to the first support and to the second support.

26. An assembly for converting light energy to electric energy, the assembly comprising:
a first number of means for converting light energy to electric energy, each of the first number of means for converting characterized by having a longitudinal dimension and a cross-sectional dimension, the longitudinal dimension being greater than four times the cross-sectional dimension, each of the means for converting characterized by having an inside longitudinal boundary and an opposing outside longitudinal boundary;
means for concentrating light energy onto each of the first number of means for converting, the means for concentrating extending no more than the height of one of the first number of means for converting;
means for supporting the first number of the means for converting and the means for concentrating in a particular fixed orientation;
an outside edge of a first means for converting from among the first number of means for converting disposed from an inside edge of an adjacent second means for converting by at least the cross-sectional dimension of the first means for converting;
wherein the first number of means for converting resides above a portion of the means for concentrating; and
wherein a portion of the means for concentrating is disposed between the inside edge of the second means for converting and the outside edge of the first means for converting.

27. An assembly for producing electric energy from light energy, the assembly comprising:
a first frame member having a length L;
a second frame member, oriented substantially parallel to the first frame member and disposed from the first frame member by a distance D, the distance D being smaller than the length L;
a concentrator comprised of a plurality of concentrator assemblies, each respective concentrator assembly in the plurality of concentrator assemblies comprising:
a first surface comprising a reflective material and characterized by a first surface edge;
a second surface comprising a reflective material and characterized by a second surface edge;
wherein the first surface and the second surface form a concave-shaped structure with an opening defined by the first surface edge and the second surface edge;
wherein the opening is operable to admit light into the concave-shaped structure;
a plurality of elongated photovoltaic modules, each respective elongated photovoltaic module from the plurality of elongated photovoltaic modules disposed within the opening of a corresponding concentrator assembly in the plurality of concentrator assemblies and characterized by a first area opposing the opening of the corresponding concentrator assembly and a second area facing another direction other than the direction of the first area,
each respective elongated photovoltaic module from the plurality of elongated photovoltaic modules comprising:
a rigid substrate; and
one or more layers of photovoltaic material disposed upon the substrate, the one or more layers of photovoltaic material collectively operable to covert light to electric energy; and
each respective elongated photovoltaic module from the plurality of elongated photovoltaic modules operable to concurrently: produce electric energy from a) light directly striking the first area of the elongated photovoltaic module; and b) light redirected by the corresponding concentrator assembly to the second area;
wherein a first elongated photovoltaic module from the plurality of elongated photovoltaic modules is associated with a first concentrator assembly from the plurality of concentrator assemblies, and the first photovoltaic module resides within the concave-shaped structure associated with the first concentrator assembly, the first photovoltaic module having an outer edge in the direction of the opening defined by the first concentrator assembly;
wherein the first surface of the first concentrator assembly is shaped at least in part as an involute of a first portion of the surface of the first photovoltaic module;
wherein the second surface of the first concentrator assembly is shaped at least in part as the involute of a second portion of the surface of the first photovoltaic module;
wherein the outer edge of the first photovoltaic module is at least as high as the first surface edge; and
wherein the outer edge of the first photovoltaic module is at least as high as the second surface edge.

28. An assembly for converting light energy to electric energy, the assembly comprising:
a first number of photovoltaic modules, each of the first number of photovoltaic modules comprising:
a substrate;
a material operable to convert light energy to electric energy, disposed on the substrate;
each of the first number of photovoltaic modules characterized by having a longitudinal dimension and a cross-sectional dimension, the longitudinal dimension being at least four times the cross-sectional dimension;
a concentrator having a first number of concentrator assemblies, each of the first number of concentrator assemblies associated with a particular photovoltaic module from the first number of photovoltaic modules, each respective concentrator assembly of the first number of concentrator assemblies comprising:
a fixed first surface and a fixed second surface, the first surface and the second surface forming a concave structure, the first surface and the second surface operable to reflect light energy, which enters the concave structure, to the particular photovoltaic module that is associated with the respective concentrator assembly;
the first fixed surface having a portion shaped as an involute of a first portion of the surface of the particular photovoltaic module that is associated with the respective concentrator assembly;
the second fixed surface having a portion shaped as an involute of a second portion of the surface of the particular photovoltaic module that is associated with the respective concentrator assembly;
the first fixed surface and the second fixed surface extending no more than the height of the particular photovoltaic module associated with the respective concentrator assembly;
a frame, comprising:
a first support with a first plurality of electric contacts disposed therein;
a second support;
each of the first number photovoltaic modules extending from the first support to the second support;
each of the first number photovoltaic modules electrically coupled to a corresponding electric contact disposed in the first support; and
the concentrator being mechanically attached to the frame;
wherein a substantial portion of light striking a first concentrator assembly from the first number of concentrator assemblies is ultimately redirected to an associated photovoltaic module from the first number of photovoltaic modules.

29. An assembly for converting light energy to electric energy, the assembly comprising:
a first number of photovoltaic modules, each of the first number of photovoltaic modules comprising:
a substrate;
a material operable to convert light energy to electric energy, disposed on the substrate;
each of the first number of photovoltaic modules characterized by having a longitudinal dimension and a cross-sectional dimension, the longitudinal dimension being at least four times the cross-sectional dimension;
a fixed concentrator having a first number of concentrator assemblies, each of the first number of concentrator assemblies associated with a particular photovoltaic module from the first number of photovoltaic modules, each respective concentrator assembly in the first number of concentrator assemblies comprising:
a first surface and a second, the first surface and the second surface forming a concave structure that is operable to reflect light energy that enters the concave structure to the photovoltaic module associated with the respective concentrator assembly;
the first surface having a portion shaped as an involute of a first portion of the surface of the photovoltaic module associated with the respective concentrator assembly;
the second surface having a portion shaped as an involute of a second portion of the surface of the photovoltaic module associated with the respective concentrator assembly;
the first surface and the second surface extending no more than the height of the photovoltaic module associated with the respective concentrator assembly;
a frame, comprising:
a first support with a plurality of electric contacts disposed therein; and
a second support;
each of the first number photovoltaic modules extending from the first support to the second support;
each of the first number photovoltaic modules electrically coupled to a corresponding electric contact in the plurality of electric contacts disposed within the first support; and
the concentrator being mechanically attached to the frame;
wherein a substantial portion of light striking a first concentrator assembly from the first number of concentrator assemblies is ultimately redirected to a first photovoltaic module from the first number of photovoltaic modules, the first photovoltaic module being associated with the first concentrator assembly.
